(19) United States
(12) Patent Application Publication
(10) Pub. No.: US 2011/0048675 A1
(43) Pub. Date: Mar. 3, 2011

(54) HEAT SINK

(75) Inventors: Shou-Biao Xu, Shenzhen City (CN); Shi-Wen Zhou, Shenzhen City (CN); Chun-Chi Chen, Tu-Cheng (TW)

(73) Assignees: Fu Zhun Precision Industry (Shen Zhen) Co., Ltd., Shenzhen City (CN); Foxconn Technology Co., Ltd., Tu-Cheng (TW)

(21) Appl. No.: 12/620,529

(22) Filed: Nov. 17, 2009

(30) Foreign Application Priority Data
Aug. 28, 2009 (CN) 200910306264.9

(51) Int. Cl. F28F 13/00; H05K 7/20

(52) U.S. Cl. 165/80.3; 361/709

(57) ABSTRACT

A heat sink includes a plurality of first fins and a plurality of second fins. Each first fin and each second fin includes an inner end and an outer end opposite to the inner end, respectively. Each of the second fins is sandwiched between two respective adjacent first fins. The inner end of each of the first fins is engagingly received in the inner end of the previous adjacent first fin, sandwiching the inner end of a corresponding second fin therebetween. The outer end of each of the first fins is engagingly received in the outer end of the previous adjacent second fin, and the outer end of each of the second fins is engagingly received in the outer end of the previous adjacent first fin.

### BACKGROUND

1. Technical Field

The disclosure relates to heat sinks and, more particularly, to a heat sink for dissipating heat generated by an electronic component.

2. Description of Related Art

With the increasing development of computer technology, electronic components such as central processing units (CPUs) of computers are being made to operate at higher operational speeds and to have greater functional capabilities. When an electronic component operates at high speed, it frequently generates large amounts of heat. The heat must be quickly removed from the electronic component to prevent it from becoming unstable or being damaged. Typically, a heat sink is attached to an outer surface of the electronic component to absorb heat from the electronic component. The heat absorbed by the heat sink is then dissipated to ambient air.

A typical heat sink includes a plurality of fins. Each fin includes a body, and two flanges extending from the body. In particular, the flanges are bent from upper and lower edges of the body, respectively. Each fin is provided with a protrusive connecting portion which extends toward a neighboring fin. A receiving aperture is defined between the body and the connecting portion. The connecting portion of the fin is received in the receiving aperture of the neighboring fin, thereby connecting the fins together. In this way, a desired number of fins can be attached together in sequence to form the heat sink. The flanges of each two neighboring fins provide an interval between the fins to allow airflow through the heat sink.

Nowadays, most electronic components are following the trend toward miniaturization. In addition, such components are frequently used in compact electronic products. An electronic component installed in a product may have only a very small surrounding space available for heat dissipation. In many cases, it is necessary or desirable to install a heat sink on the electronic component. How to improve the heat-dissipation efficiency of a heat sink that is used in a very small heat-dissipation space is an ongoing problem in the electronics industry. One approach to this problem is to seek to increase the density of the fins per unit area or unit volume of the heat sink. However, for the above-described typical heat sink, this is difficult to achieve. Due to the flanges of each fin and limitations inherent in the technology of manufacturing the fins, the density of the fins is limited. Another approach to improve the heat-dissipation efficiency of a heat sink is to increase the number of fins, thereby increasing the heat dissipation area of the heat sink. However, the increased number of fins increases the volume of the heat sink.

What is needed, therefore, is a heat sink which can be used in a limited heat-dissipation space and which has a large number of fins.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric, partly exploded view of a heat sink in accordance with an embodiment of the disclosure.

FIG. 2 is an enlarged view of parts of the heat sink of FIG. 1.

FIG. 3 is a side view of a first fin of the heat sink of FIG. 2.

FIG. 4 is a side view of a second fin of the heat sink of FIG. 2.

FIG. 5 is a top plan view of the heat sink of FIG. 1.

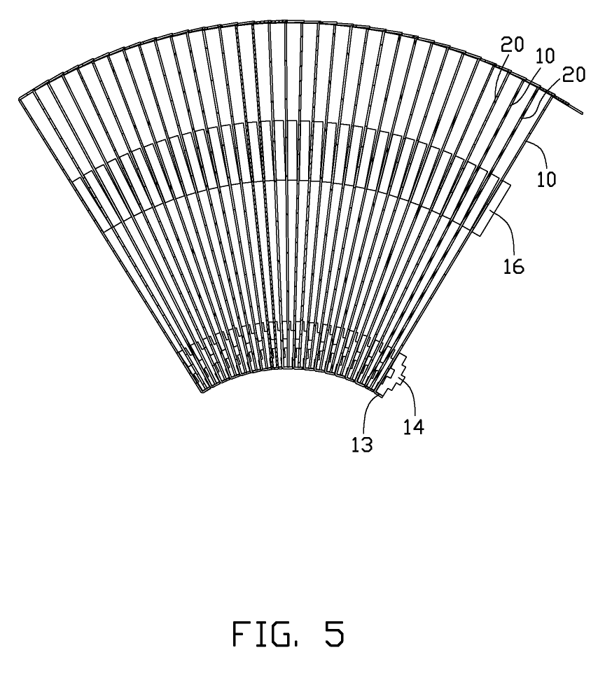

### DETAILED DESCRIPTION

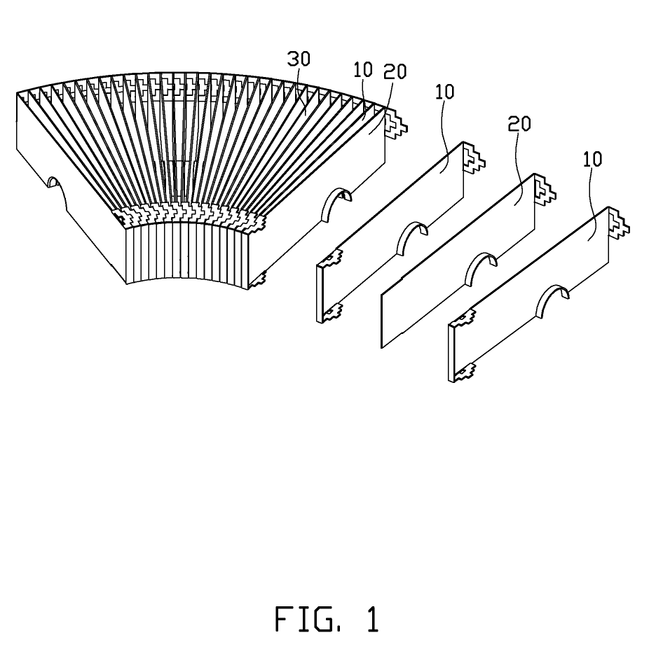

Referring to FIG. 1, a heat sink in accordance with an embodiment of the disclosure is illustrated. The heat sink has a truncated sector-like configuration; or viewed another way, the heat sink has a shape like part of an annulus. The heat sink includes a plurality of first fins 10 and a plurality of second fins 20. The second fins 20 are alternately arranged with the first fins 10. That is, each of the second fins 20 is sandwiched between two adjacent first fins 10. Each of the first fins 10 is spaced from the neighboring second fin 20. Thereby, a plurality of air passages 30 between the first fins 10 and the second fins 20 is formed. In the present embodiment, the number of first fins 10 is one more than the number of second fins 20. The first and second fins 10, 20 have the same height as each other. Each of the first and second fins 10, 20 is oriented along a radius of a circle defined by the shape of the part of the annulus. Each first and second fin 10, 20 extends from an inner end of the heat sink to an outer end of the heat sink. In other embodiments, a larger number of the first and second fins 10, 20 can be used, such that the first and second fins 10, 20 cooperatively form an annular heat sink.

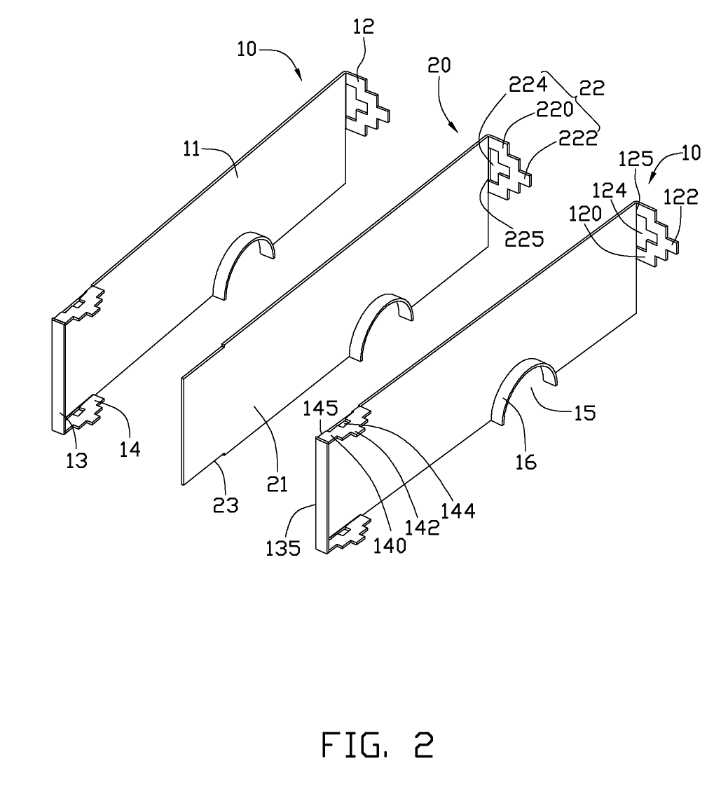

Also referring to FIG. 2, each of the first fins 10 includes a rectangular body 11, a first latching portion 12 extending perpendicularly from an outer and shorter edge of the body 11, a wing portion 13 extending perpendicularly from an inner and shorter edge of the body 11, and two second latching portions 14 extending perpendicularly from upper and lower edges of the body 11 and located near the wing portion 13. The wing portion 13 is parallel to the first latching portion 12. The second latching portions 14 are perpendicular to the wing portion 13. The first and second latching portions 12, 14 and the wing portion 13 of each first fin 10 extend towards a previous adjacent second fin 20.

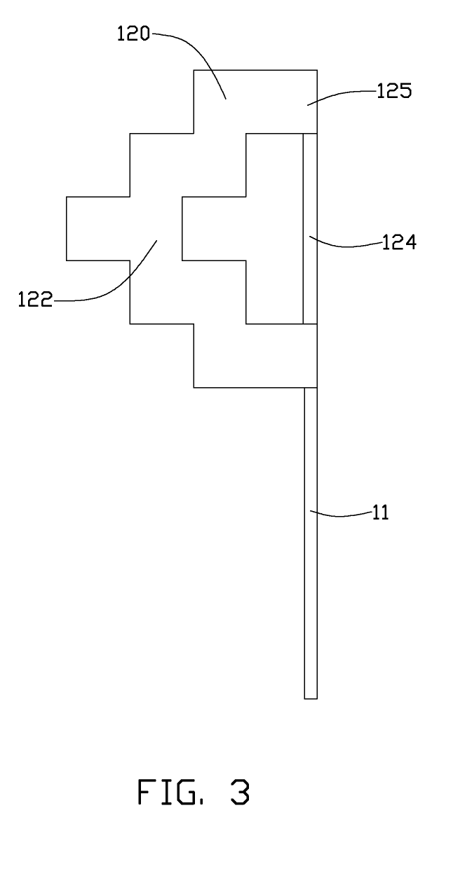

The first latching portion 12 includes a rectangular flange 120 and a protrusive T-shaped connecting portion 122 extending towards the previous adjacent second fin 20. A T-shaped receiving aperture 124 is defined in the first latching portion 12, and is located adjacent to the outer edge of the body 11. Also referring to FIG. 3, the receiving aperture 124 extends through a folding portion 125 between the body 11 and the flange 120. Each of the second latching portions 14 includes a rectangular flange 140 and a protrusive T-shaped connecting portion 142 extending towards the previous adjacent second fin 20. A T-shaped receiving aperture 144 is defined in each second latching portion 14. The receiving aperture 144 extends through a folding portion 145 between the body 11 and the flange 140. The wing portions 13 of the first fins 10 are equal in width to the flanges 140 of the second latching portions 14. The connecting portion 142 of the first fin 10 is approximately equal in size and shape to the receiving aperture 144 of the previous adjacent first fin 10, so that the connecting portion 142 is received in the receiving aperture 144. At the same time, the wing portion 13 of the first fin 10 abuts a folding portion 135 between the wing portion 13 and the body 11 of the previous adjacent first fin 10, thereby providing an interval between inner ends of two adjacent first fins 10. The first latching portion 12 of the first fin 10 has an extending length toward the previous adjacent second fin 20 larger than that of each second latching portion 14.

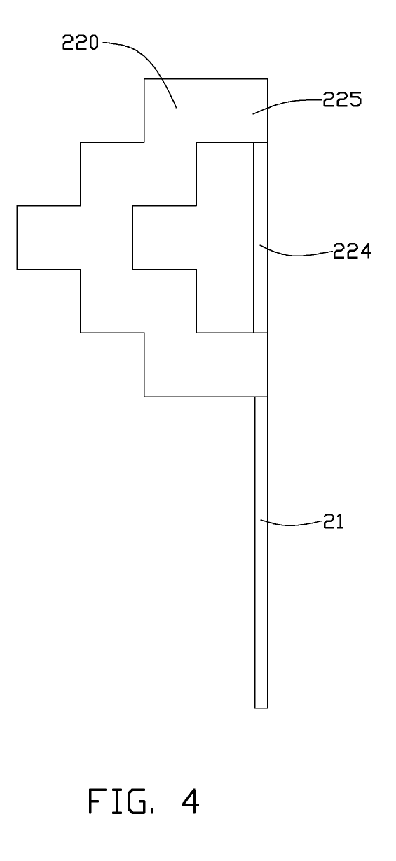

Each of the second fins 20 includes a rectangular body 21 and a third latching portion 22 extending perpendicularly from an outer and shorter edge of the body 21. The third latching portion 22 includes a rectangular flange 220 and a protrusive T-shaped connecting portion 222 extending towards the previous adjacent first fin 10. A T-shaped receiving aperture 224 is defined in the third latching portion 22, corresponding to the connecting portion 222. Also referring to FIG. 4, the receiving aperture 224 extends through a folding portion 225 between the body 21 and the flange 220.

The connecting portion 122 of the first fin 10 is approximately equal in size and shape to the receiving aperture 224 of the previous adjacent second fin 20, so that the connecting portion 122 is received in the receiving aperture 224. At the same time, the flange 120 of the first fin 10 abuts the folding portion 225. The connecting portion 222 of the second fin 20 is approximately equal in size and shape to the receiving aperture 124 of the previous adjacent first fin 10, so that the connecting portion 222 is received in the receiving aperture 124. At the same time, the flange 220 abuts the folding portion 125.

In this embodiment, the connecting portions 122 of the first fins 10 have the same shape as the connecting portions 222 of the second fins 20. The flanges 120, 220 of the first and second fins 10, 20 are equal in width to each other, thereby providing same intervals between outer ends of every two adjacent first and second fins 10, 20. In other embodiments, the connecting portions 122 of the first fins 10 have different shapes from the connecting portions 222 of the second fins 20, and the flanges 120, 220 of the first and second fins 10, 20 have different widths from each other, thereby providing different intervals between outer ends of two adjacent first and second fins 10, 20. In this embodiment, the body 21 of each second fin 20 has two corners of an inner end thereof cut away to form two cutouts 23. Each of the bodies 11, 21 of the first and second fins 10, 20 defines a semicircular opening 15 at a center of a lower edge thereof, and forms a semicircular flange 16 extending perpendicularly and bordering the opening 15. The flanges 16 of the first and second fins 10, 20 cooperatively form an arc-shape groove for receiving at least part of a heat pipe (not shown) therein. In other embodiments, the bodies 11, 21 of the first and second fins 10, 20 may omit the openings 15 and the flanges 16, according to actual needs.

The first latching portions 12 of the first fins 10 and the third latching portions 22 of the second fins 20 are alternately interlinked with each other to cooperatively form an outer arc-shaped surface. The connecting portion 142 of each of the first fins 10 extends through a corresponding cutout 23 of the previous adjacent second fin 20, and is received in the receiving aperture 144 of the previous adjacent first fin 10. The inner end of each of the second fins 20 abuts the wing portion 13 of the two adjacent first fins 10. Each of the wing portions 13 of the first fins 10 abuts the folding portion 135 of the previous adjacent first fin 10, thereby cooperatively forming an inner arc-shaped surface. The inner arc-shaped surface can be attached to another element, such as a heat-conducting block, post or pole. The flanges 120, 220 of the first and second fins 10, 20 each have a width larger than the flanges 140 of the second latching portions 14.

The second latching portion 14 of each first fin 10 is linked with the second latching portion 14 of the previous adjacent fin 10, and the inner end of the intervening second fin 20 is sandwiched between the inner ends of the two adjacent first fins 10. With the above-described configuration, in a same limited available heat-dissipation space, the heat sink of the present disclosure can incorporate two times as many fins as a heat sink of the related art. Therefore, the heat sink of the present disclosure provides a much larger heat-dissipation area.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat sink comprising:
a plurality of first fins each comprising an inner end and an outer end opposite to the inner end; and
a plurality of second fins each comprising an inner end and an outer end opposite to the inner end;
wherein each of the second fins is sandwiched between two respective adjacent first fins, the inner end of each of the first fins is engagingly received in the inner end of the previous adjacent first fin, sandwiching the inner end of a corresponding second fin therebetween, the outer end of each of the first fins is engagingly received in the outer end of the previous adjacent second fin, and the outer end of each of the second fins is engagingly received in the outer end of the previous adjacent first fin.

2. The heat sink as claimed in claim 1, wherein the heat sink has a generally truncated sector-like configuration.

3. The heat sink as claimed in claim 1, wherein each of the first fins comprises a first latching portion located at the outer end thereof and two second latching portions extending from upper and lower edges thereof and located at the inner end thereof, and the two second latching portions are engagingly received in the second latching portions of the previous adjacent first fin.

4. The heat sink as claimed in claim 3, wherein each of the first fins further comprises a wing portion located at the inner end thereof, and the wing portions of the first fins cooperatively form an inner generally arc-shaped surface.

5. The heat sink as claimed in claim 4, wherein the inner end of each of the second fins abuts the wing portion of the next adjacent first fin.

6. The heat sink as claimed in claim 4, wherein each of the second fins comprises a third latching portion located at an outer end thereof, and the third latching portion of each second fin is engagingly received in the first latching portion of the previous adjacent first fin.

7. The heat sink as claimed in claim 6, wherein the first and second latching portions and the wing portion of each of the first fins extend perpendicularly towards the previous adjacent second fin, and the third latching portion of each of the second fins extends perpendicularly towards the previous adjacent first fin.

8. The heat sink as claimed in claim 7, wherein the second latching portions of each of the first fins are parallel to each other and perpendicular to the first latching portion.

9. The heat sink as claimed in claim 6, wherein the first latching portions of the first fins and the third latching portions of the second fins cooperatively form an outer generally arc-shaped surface.

10. The heat sink as claimed in claim 6, wherein each of the first, second and third latching portions comprises a flange, and a connecting portion extending towards the previous adjacent second or first fin, respectively, the connecting portion having a receiving aperture defined therein, the receiving aperture corresponding to the respective connecting portion of a next adjacent second or first fin, respectively.

11. The heat sink as claimed in claim 10, wherein the connecting portion of the first latching portion of each of the first fins is approximately equal in size to the receiving aperture of the third latching portion of the previous adjacent second fin, and the connecting portion of the third latching portion of each of the second fins is approximately equal in size to the receiving aperture of the first latching portion of the previous adjacent first fin.

12. The heat sink as claimed in claim 11, wherein the flange of the first latching portion has a width equal to the flange of the third latching portion, thereby providing same intervals between the outer ends of every two adjacent first and second fins.

13. The heat sink as claimed in claim 12, wherein the flange of the first latching portion of each of the first fins has a width larger than that of the wing portion of the first fin.

14. The heat sink as claimed in claim 11, wherein the connecting portions of the first latching portions of the first fins have the same shape as the connecting portions of the third latching portions of the second fins.

15. The heat sink as claimed in claim 14, wherein the first and second fins have the same height as each other.

16. The heat sink as claimed in claim 15, wherein each of the second fins has two corners of the inner end thereof cut away to form two cutouts, with the second latching portion of the next adjacent first fin extending through the cutouts.
